(19) United States
(12) Patent Application Publication
(10) Pub. No.: US 2006/0160251 A1
(43) Pub. Date: Jul. 20, 2006

(54) Method in the fabrication of a memory device

(75) Inventors: Peter Dyreklev, Linkoping (SE); Anders Hagerstrom, Linkoping (SE); Hans Gudesen, Brussels (BE); Per-Erik Nordal, Asker (NO); Olle Hagel, Linkoping (SE)

Correspondence Address: BIRCH STEWART KOLASCH & BIRCH, PO BOX 747, FALLS CHURCH, VA, 22040-0747, US

(73) Assignee: Thin Film Electronics ASA, Oslo (NO)

(21) Appl. No.: 11/319,383

(22) Filed: Dec. 29, 2005

(30) Foreign Application Priority Data
Dec. 30, 2004 (NO) 20045727

(51) Int. Cl. H01L 21/00; H01L 21/8242

(52) U.S. Cl. 438/3; 438/240

(57) ABSTRACT

In a method for fabricating a memory device based on an electrically polarizable memory material in the form of an electret or ferroelectric material, the memory device comprises one or more layers with circuit structures provided exclusively or partially in a printing process. At least one protective interlayer is provided between at least two layers in the memory device, said protective interlayer exhibiting low solubility as well as low permeability for any solvents employed in the deposition of the other layers in the device. Use in fabricating a memory device, particularly a passive matrix-addressable memory device with an electret or ferroelectric memory material.

The present invention concerns a method in the fabrication of a memory device based on an electrical polarizable memory material in the form of an electret or ferroelectric material, wherein the device comprises one or more layers with circuit structures provided exclusively or partially in a printing process, wherein said one or more layers are deposited in sequential deposition steps on a common substrate, one on top of the other in complete or partial overlap or side by side, and wherein at least one layer is deposited with the layer material dissolved in a solvent.

Particularly the present invention concerns materials and manufacturing technologies for electronic circuits based on organic materials that are applied by printing processes.

Even more particularly the present invention is applicable for printing of a conducting polymer electrode on a ferroelectric polymer, but it is not restricted to that use.

Organic electronics fabricated by printing methods have been shown by many researchers and companies. The majority describes devices where semiconducting properties of the organic materials are used to realise the device function. Printing of all-polymer field effect transistors have been published by Garnier et al. [Garnier, F., R. Hajlaoui, et al. (1994). “All-polymer field-effect transistor realized by printing techniques.” Science 265(16 Sep. 1994): 1684-1686.] In this paper the authors describe how a field effect transistor is fabricated by printing of organic conducting and semiconducting materials. Furthermore it is claimed that such a device could be made using different conducting polymers such as polyaniline, polypyrrole and polythiophene. The authors write “A field-effect transistor has been fabricated from polymer materials by printing techniques. The device characteristics, which show high current output, are insensitive to mechanical treatments such as bending or twisting. This all-organic flexible device realized with mild techniques, opens the way for large-area, low-cost plastic electronics.” The technique used for printing in this paper seems to be far away from conventional high volume printing methods, but still the materials are deposited by a method not common for micro-electronics manufacturing.

The use of more established printing methods is e.g. reported by Hebner et al. [Hebner (1998). “Ink-jet printing of doped polymers for organic light emitting devices.” Applied Physics Letters 72(5): 519-521]. The authors claim “Ink-jet printing was used to directly deposit patterned luminescent doped-polymerfilms. The luminescence of polyvinylcarbazol (PVK) films, with dyes of coumarin 6(C6), coumarin 47(C47), and nile red was similar to that of films of the same composition deposited by spin coating. Light emitting diodes with low turn-on voltages were also fabricated in PVK doped with C6 deposited by ink-jet printing.” Dyed organic polymer was printed to form features in the size range 150-200 μm and having a thickness of 40-70 nm. In the reported work only the active emissive layer is printed while the metallic electrodes are deposited by physical vapour deposition.

Other devices fabricated by printing methods are reported by Andersson et al. in a paper entitled “Active Matrix Displays Based on All-Organic Electrochemical Smart Pixels Printed on Paper” [Andersson, P., D. Nilsson, et al. (2002). “Active Matrix Displays Based on All-Organic Electrochemical Smart Pixels Printed on Paper.” Adv. Materials 14(20): 1460-1464]. There the authors have printed conducting polymer structures to form both transistors, resistors as well as display elements. The printed layers are PEDOT:PSS formed by either additive printing or subtractive patterning.

Printing of PEDOT:PSS has also been used for making the transducer for a humidity sensor. This was reported by Nilsson et al. [Nilsson, D., T. Kugler, et al. (2002). “An all-organic sensor-transistor based on a novel electrochemical transducer concept printed electrochemical sensors on paper.” Sensors and Actuators B 86: 193-197].

Another method of utilising printing technology for the manufacturing of an electronic device is reported by Huang et al. [Huang, Z., P. C. Wang, et al. (1997). “Selective deposition of conducting polymers on hydroxyl-terminated surfaces with printed monolayers of alkylsiloxanes as templates.” Langmuir (13): 6480-6484]. Self-assembled monolayers are printed to be used as templates for the deposition of conducting polymer microstructures. I.e. the conducting polymer itself is not printed.

During recent years, memory structures and devices based on organic materials as the memory substance, in particular ferroelectric polymers, have been proposed and demonstrated. Of particular interest in the present context are those that can be built on flexible substrates and that lend themselves well to simple and high volume manufacturing processes. Typically, this concerns purely passive tags or devices where active electronic components are not required in the memory structure itself. Each memory cell is a capacitor-like structure where the memory substance, e.g. a ferroelectric polymer is located between a pair of electrodes and where the memory cell is accessed via conductors linking the electrodes to electronic driver or detection circuitry. The latter may e.g. be located on the periphery of the memory array or on a separate module. Depending on the application, each tag or device may contain from one individual memory cell and up to several millions of cells arranged in matrix arrays.

Manufacturing issues are of decisive importance in applications where low cost tags are to be made in very high volumes. In the existing literature on organic-based memory devices there has been little focus on printing technologies for creating electrical structures such as interconnect wiring and cell electrodes.

U.S. patent application No. 2003/0,230,746A1 discloses a memory device comprising: a first semiconducting polymer film having a first side and a second side, wherein said first semiconducting polymer film includes an organic dopant; a first plurality of electrical conductors substantially parallel to each other coupled to said first side of said first semiconducting polymer layer; and a second plurality of electrical conductors substantially parallel to each other, coupled to said second side of said first semiconducting polymer layer and substantially mutually orthogonal to said first plurality of electrical conductors, wherein an electrical charge is localized on said organic dopant. It is claimed that the conducting patterns can be inkjet printed, but no other printing techniques are stated. The described memory device uses a semiconducting polymer layer including a dopant and writing of information via an electrical charge localized on the dopant and the memory device is volatile; the information is lost if no power is applied.

International published application WO 02/0,029,706A1 discloses an electronic bar code comprising: a bar code circuit that stores a code that is electronically readable, wherein the code is defined by a polymer printing process; and an interface coupled to the bar code circuit to allow a bar code reader to access the code stored in the bar code circuit.

A fully printed memory device based on organic memory materials would be advantageous from a cost point of view. The use of existing printing technology would be a requirement for an efficient and cost-effective integration of the device printing with other parts of the manufacturing of a low cost product. One such requirement is the ink formulations that are used today or possible to use. A printing ink needs a solvent to achieve the correct viscosity and drying properties for successful deposition of the desired pattern. But success depends on managing the problem that the solvent in the ink may swell or dissolve an already existing layer and hence prevent the formation of the desired structure.

Hence a primary object of the present invention is to provide a manufacturing method involving printing processes and which obviates the above-mentioned problem.

The above-stated object as well as further features and advantages are achieved with a method according to present invention which is characterized by providing at least one protective interlayer between at least two layers in the memory device, said protective interlayer exhibiting low solubility and low permeability for any solvents employed in the deposition of the other layers in the device, whereby a dissolution, swelling or chemical damage of said one or more layers with circuit structures is prevented.

Additional features and advantages will be apparent from the appended dependent claims 2-12.

The invention shall be described in more detail in the following in connection with discussions of exemplary embodiments and examples, and with reference to the appended drawing figures, of which

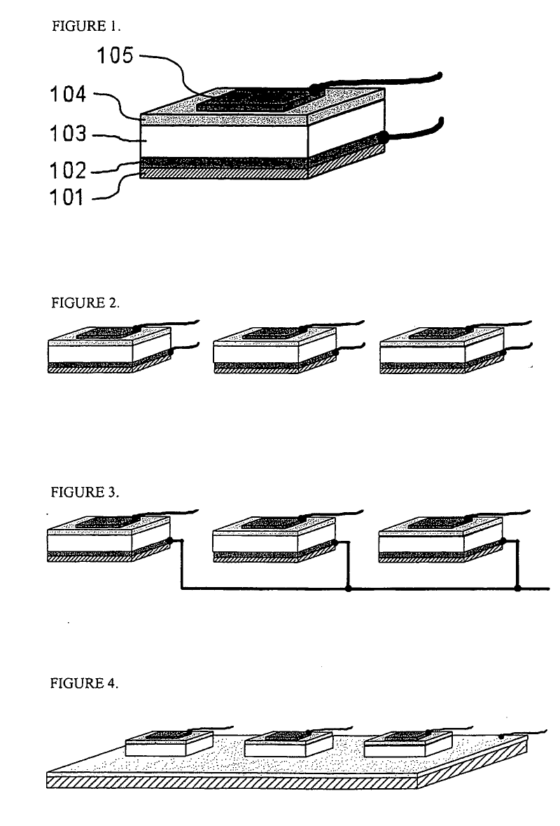

FIG. 1 shows the generic memory device structure made with use of the method according to the present invention,

FIGS. 2-4 examples of arrayed memory cells in a memory device made with use of the method according to the present invention,

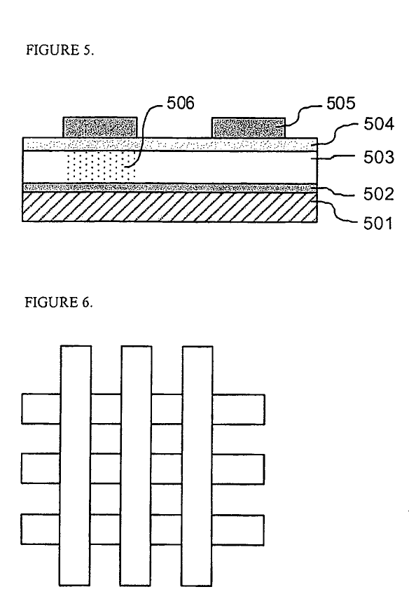

FIG. 5 a passive matrix-addressable array of memory cells in a memory device made with use of the method according to the present invention,

FIG. 6 a cross-section of a matrix-addressable memory cell made with use of the method according to the present invention,

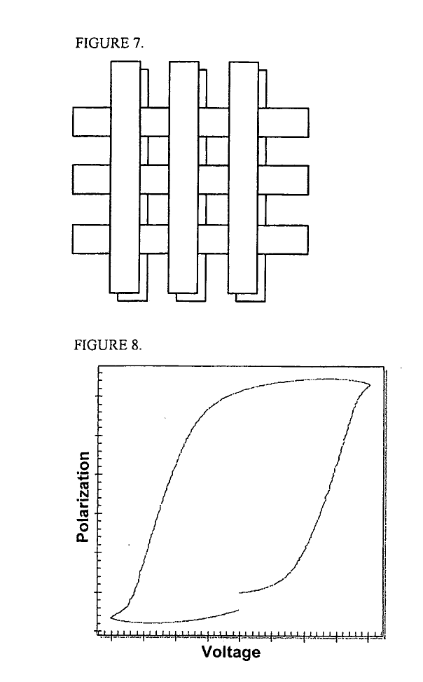

FIG. 7 a stacked array of passive matrix-addressable memory cells made with use of the method according to the present invention,

FIG. 8 polarization hysteresis data obtained from a device made with use of the method according to the present invention, and

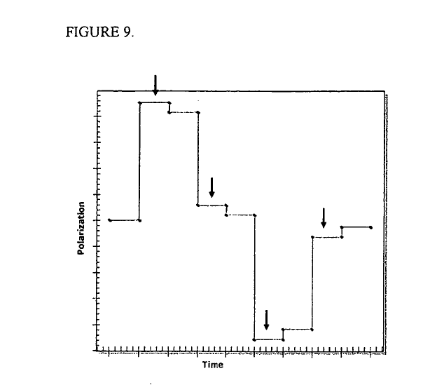

FIG. 9 pulse polarization data obtained from a device fabricated according to the method of the present invention.

As an aid to understanding the present invention, there shall now be given a brief description of a representative method for fabricating a device structure using the present invention. The manufacturing method is exemplified by the fabrication of a printed organic memory device which is of particular relevance since it lends itself well to utilize the present invention.

The memory cells in question consist of a pair of electrodes contiguous to a volume of an electrically polarizable memory substance, typically in the form of a ferroelectric polymer, and typically in a parallel-plate capacitor-like structure. The different parts of the structure illustrated in FIG. 1 are a substrate 101, a first electrode 102, a memory layer 103, a protective layer 104, and a second electrode 105.

This simple structure is in strong contrast to memory cells in traditional memory technologies, where one or more transistors or other semiconducting elements are required in association with each cell, and the consequences for low cost manufacturing are dramatic. In the following, memory devices based on the simple structure referred above shall be referred to as a “passive memory device”.

A plurality of memory cells may be arranged side by side on a common substrate, each cell having the generic structure shown in FIG. 1, where electrical access to each cell is by wire connection to each of the two electrodes 102; 105, respectively. Depending on the application, the size, shape, spatial distribution and electrical connection arrangement for a plurality of memory cells may vary; some examples are shown in FIGS. 2-4. FIG. 2 shows an array of individual cells, each of which has a wire connection to the two electrodes. Further electrical connections to the wires may take many forms, e.g. ending in contact pads on a common substrate. FIG. 3 shows a similar arrangement, but where all bottom electrodes are electrically connected in order to reduce wiring complexity. FIG. 4 is a variant where a plurality of cells are arranged on a conducting surface which forms a common bottom electrode in each cell, and where each cell has its own, individually electrically connected top electrode. This arrangement is similar to the one shown in FIG. 3 in that it requires less connecting electrodes than the arrangement of FIG. 2. All structures shown in FIGS. 1-4 carry the protective layer on top of the ferroelectric memory layer and below the top electrode layer.

Substrates shall in the present context typically be flexible, although this may not always be the case. They may be electrically insulating, e.g. in the form of a sheet of paper, a plastic foil, glass, board, carton or a composite material of any of these materials. Alternatively, they may be electrically conducting, e.g. in the form of a metal foil with an insulating coating to avoid electrical short circuits. The arrayed memory cells on a given substrate may be electrically accessed individually or in parallel from external circuitry by means of mechanical contacts pads on the substrate. Alternatively, there may be active electrical circuitry incorporated on or in the substrate itself. If the latter is flexible, the circuitry shall typically be located in thin film semiconducting material based on silicon (amorphous or polycrystalline) or organic materials (polymers or oligomers).

In cases where large numbers of memory cells are involved, a matrix-addressable array of memory cells as shown in FIGS. 5-7 provides a simple and compact means of providing electrical access to individual cells for writing, reading and erasing operations. This memory device configuration is termed a passive matrix device since there are no switching transistors present for switching a memory cell on and off in an addressing operation. Basically a memory device of this kind is formed with a first pattern of parallel strip-like electrodes 502, which is located on a substrate 501 and covered by a global layer of ferroelectric memory material 503, i.e. a ferroelectric polymer, which is covered by a protective layer 504, over which are provided another electrode pattern 505 comprising likewise parallel strip-like electrodes, but oriented orthogonally to the first electrode pattern, so as to form an orthogonal electrode matrix. The ferroelectric memory material may also be applied as a non-continuous layer, i.e. a pattern. The first electrode pattern can e.g. be regarded as the word lines of a matrix-addressable memory device, while the second electrode pattern can be regarded as the bit lines thereof. At the crossings between the word lines and bit lines, a memory cell 506 is defined in the matrix in the layer of memory material. Thus the memory device will comprise a plurality of memory cells corresponding to the number of electrode crossings in the matrix.

An interesting aspect of the basic structures described above is that they provide opportunities for stacking of memory arrays on top of each other, cf. FIG. 7. This means that very high volumetric data storage densities can be achieved, and large total data storage capacities can be realized on a small footprint and in a small volume.

The electrodes may be a conducting or semiconducting material, which generally can be applied from solid or liquid phase by a wide range of physical and chemical means. Conductive and semiconductive materials can be suspended or dissolved to form inks, e.g. based on conductive metals (e.g. silver paste), conductive metal alloys, conductive metal oxides, carbon black, semiconductive metal oxides and intrinsically conductive organic polymers (e.g. polyaniline, PEDOT).

The memory material in the memory cells may typically be an organic ferroelectric material, e.g. fluorine-containing oligomers or polymers such as vinylidene fluoride or its polymer polyvinylidene fluoride (PVDF) or copolymers such as poly(vinylidenefluoride-trifluorethylene) (PVDF-TrFE). Other examples are polymers with strongly polarizable end groups such as polyvinylidene cyanide (PVCN). Optimization of materials can take place using copolymers, terpolymers and blends (e.g. with polymethylmetacrylate PMMA).

In the manufacture of memory devices according to the present invention, it is a requirement that the printed electrically conducting material used in electrodes, interconnecting wiring, pads etc. shall conform to standard physical and chemical requirements for achieving printability. This shall depend on the printing process chosen in each case, but generally includes rheological, solubility and wetting properties, as well as issues concerning cost, toxicity, etc. Drying properties, in particular the volatility of solvents used, shall in large measure influence the attainable speed in the manufacturing process. The latter is of paramount importance in high volume processes, e.g. in the production of ultra low cost tags and labels.

In many instances of practical interest, and as shall be described in more detail below, conductive inks based on intrinsically conductive organic polymers are preferred. Inks based on PEDOT:PSS possess qualities that make them particularly useful in the present context, and shall be described in more detail below.

Specifically the invention is exemplified by a ferroelectric memory device, utilizing conducting polymer electrodes. In this embodiment one of the electrodes is deposited by a printing method. The protective layer also consists of a conducting polymer having the following properties:
1. Withstands water or solvents used for the printing process.
2. Does not add a significant (for the device design in question) lateral conductivity, creating leakage current between printed conducting polymer features intended to be electrically separated.
3. The electrical properties along the direction through the protective film (the direction between the opposing electrodes) must be of sufficiently high conductivity or high dielectric constant in order to minimize the electrical field over the protective layer.
4. Promotes good adhesion to the ferroelectric memory layer and to the electrode layer to be printed on top of the protective layer.

PEDOT:PSS is one material that fulfills these requirements. PEDOT:PSS consists of PEDOT and PSS in a water and isopropanol suspension. PEDOT is the acronym for poly(ethylenedioxythiophene), an conjugated organic polymer, and PSS is the counter ion poly(styrenesulphonate). PEDOT:PSS is e.g. commercially available under the trade name Baytron P VP CH8000. To the suspension the following is further added: a cross-linking agent, glycidyloxypropyltrimethoxysilane (trade name Silquest A187) (0,45%) and fluorosurfactant (DuPont Zonyl FS-300) (0.4%). The cross-linking agent renders the material insoluble and the surfactant creates a compatibility with both hydrophobic and hydrophilic materials.

A memory device is fabricated in the following way, which describes the process for obtaining one memory cell, but can be extended to form a very large number of cells simultaneously.

A polyethyleneterephtalate (PET) substrate is coated by a conducting polymer (PEDOT-PSS) layer (Agfa Orgacon™TM). The conducting polymer layer is then patterned by a de-activation process to form a bottom electrode for the memory cell. The activation process renders certain areas of the layer non-conducting and hence forms a functional layer. The patterning is in this embodiment made by photolithography, where the desired pattern is defined by exposing a photoresist layer with UV-light thorough a mask. The photoresist is then developed with a wet chemical developer, resulting in a pattern where the areas for de-activiation are exposed while areas intended for keeping their properties are protected by the photo resist. The photolithography process uses photo resist Shipley Microposit S1813 which is spin coated to a thickness of 1,3 μm and baked at 100° C. for 20 min. on a hotplate, both steps are done in a Karl Süss RC8THP semiautomatic resist coater. The photoresist is exposed in a Karl Süss MA8 mask aligner and subsequently developed in a bath with developer NMD-3 from Tokyo Ohka Kogyo Co.

The de-activation process is done by immersing the structure in NaOC1, 1% solution in water, for 30 seconds. Then the photoresist is removed by dissolution in acetone and the structure is rinsed in isopropanol.

The active memory layer is then deposited on the bottom electrode. The deposition is done by spin coating from solution. The ferroelectric polymer poly(vinylidenetrifluoroethylene) (PVDF-TrFE) is dissolved in diethylcarbonate at the concentration 3%. The solution is deposited on the substrate and spin coated to form a film with thickness 120 nm. The film is subsequently annealed in 140° C. for 30 min.

The interface layer is formed on top of the ferroelectric polymer by depositing a global layer by spin coating. The interface layer consists of PEDOT:PSS deposited from a water suspension. The water suspension contains a flurosurfactant and a silane based cross-linking agent (Silquest A187) rendering the PEDOT:PSS film insoluble after deposition and anneal. The thickness of the layer is 40 nm and it is annealed at 130° C. for 60 min. in convection oven.

After this process step the top electrode PEDOT:PSS is deposited by screen printing.

All process steps described above can be realized by printing means. E.g. in the patterning process for the bottom electrode, a protecting layer corresponding to the photo patterned resist can be formed by printing.

The resulting device from the above described fabrication process was then electrically characterized for investigation of its properties. The ferroelectric response was first measured by a polarization hysteresis measurement. Such a measurement consists of applying a voltage to the electrodes, creating an electric field over the memory layer. The voltage is varied as a triangular wave and the polarizing current is integrated over time. The recorded polarization is plotted versus applied voltage for one period. The result is shown in FIG. 8. The voltage is plotted along the horizontal axis and the polarization is plotted along the vertical axis, both shown with arbitrary units. The presence of a hysteresis loop is the proof of a functional ferroelectric device.

Furthermore, a pulse polarization measurement was carried out. Short voltage pulses were applied to the electrodes, and the polarization charge was recorded. The pulse train consists of two positive pulses followed by two negative pulses, all with the same absolute amplitude. This measurement protocol is often referred to as PUND (Positive Up, Negative Down). The recorded pulse polarization is plotted in a diagram shown in FIG. 9, where the time is plotted along the horizontal axis and the polarization is plotted along the vertical axis, both axis having arbitrary units. A functional ferroelectric device is verified by the relation of the pulse amplitudes at the first vs. third and fifth vs. seventh pulses, respectively. The pulses are indicated in FIG. 9 by arrows. The first polarization pulse is significantly larger than the third, verifying a large switching polarization compared to the smaller non-switching polarization. Correspondingly, the fifth and seventh pulses show this for the reverse direction of the polarization.

Ferroelectric polymer memory can be produced in non-lithographic continuous production processes. This allows very high through-put, e.g. if reel to reel production is utilized. A basic problem related to ferroelectric polymer memory is the post-deposition annealing steps, typically involving 10-30 minutes heating at temperatures between 120° C. and 140° C. If organic interlayers are included in the memory cell, they require additional annealing procedures. Further anneal steps will be required if multistack memory architectures are exploited, as many as 8-16 layers is possible in a polymer memory device. The total annealing time of such a stack may amount to more than 6 hours. Clearly this is not compatible with reel to reel, ink jet or similar non-lithographic high speed processes. Accordingly it is of vital necessity in order to realize such a memory system that both the individual anneal steps as well as the total annealing time is substantially reduced, preferably to seconds (<10s) rather than minutes. This applies both to the memory film as well as to the protective interlayer film.

A possible route to achieve this is to apply infra-red (IR) and/or microwave-based annealing etc. Spectral absorption matching is generally simple to achieve in the cases of present interest, involving aqueous or organic liquid-based solvents and organic solids. Using commercially available IR and microwave radiation sources, melt/anneal cycle times down to less than 5 seconds have been demonstrated in polymer films by the present applicants.

Electrode materials based on polymeric conducting materials, e.g. involving sulphonic acids (PEDOT:PSS), require a certain relative humidity (RH) in order to function properly. Typically such RH should be within 20-60%. This causes problems in the manufacturing process, which involves “dry” conditions (<0.1% RH). There are additional problems related to the fact that in a packaged chip containing CMOS circuitry, there is an absolute necessity that there is no moisture present.

Less strict requirements may reside in systems using organic circuitry, and especially so in systems with no active circuitry or even multiplexing components. In these cases a polymer memory device will consist of just the polymeric memory film and the organic electrodes. A possible approach to maintain acceptable RH conditions in this application will be to include a “moisture” powder, e.g. in the shape of a thin film, within the packaged device. Such moisture film may be tailor made to maintain a fixed RH level, e.g. 40%, irrespective of external RH and temperature levels

Following deposition, the protective layer may be subjected to ultraviolet (UV) radiation to promote crosslinking. This is a well-known technique, and may in certain cases be combined with specific additives that may be activated by the UV radiation. This can be used to provide flexibility, speed and control in a fast-moving manufacturing situation.

Finally it should be understood that the present invention is by no means restricted to a specific printing process, as dependent on its adaptability, any presently known printing process may be applied in the present invention. Neither is it precluded that novel and future printing process may be equally well suited for applications with the present invention.

1. A method in the fabrication of a memory device based on an electrical polarizable memory material in the form of an electret or ferroelectric material, wherein the device comprises one or more layers with circuit structures provided exclusively or partially in a printing process, wherein said one or more layers are deposited in sequential deposition steps on a common substrate, one on top of the other in complete or partial overlap or side by side, and wherein at least one layer is deposited with the layer material dissolved in a solvent,
characterized by providing at least one protective interlayer between at least two layers in the memory device, said protective interlayer exhibiting low solubility and low permeability for any solvents employed in the deposition of the other layers in the device, whereby a dissolution, swelling or chemical damage of said one or more layers with circuit structures is prevented.

2. A method according to claim 1,
characterized by depositing the protecting layer as a global layer.

3. A method according to claim 1,
characterized by depositing the protecting layer as a patterned layer.

4. A method according to claim 1,
characterized by selecting the electret or ferroelectric material as one or more of a polymer, copolymer, oligomer, co-oligomer, or blends or composites thereof.

5. A method according to claim 4,
characterized by selecting said electret or ferroelectric material as one or more of poly(vinylidene difluoride) (PVDF), poly(vinylidene trifluoroethylene) copolymer (P(VDF-TrFE)), polyurea, odd nylons, or poly(vinyl cyanide).

6. A method according to claim 4,
characterized by building said memory device on a flexible substrate.

7. A method according to claim 4,
characterized by building said memory device as a passive matrix-addressable array of capacitor-like structures.

8. A method according to claim 1,
characterized by selecting a protecting layer material with a large dielectric constant, preferably larger than 10 in the frequency range 1 kHz-1 GHz.

9. A method according to claim 1,
characterized by selecting a protecting layer material as one or more of a conducting polymer, or a conducting polymer with additives.

10. A method according to claim 1,
characterized by selecting one or more protecting layer materials comprising molecular moieties linked to phosphonic acid groups or salts of the same.

11. A method according to claim 10,
characterized by said one or more material comprising poly(vinylphosphonic acid) (PVPA).

12. A method according to claim 1,
characterized by selecting a protecting layer material as a conducting polymer chosen from the groups polythiophene, polypyrrole or polyaniline, or their derivatives.

13. A method according to claim 12,
characterized by selecting the conducting polymer as poly(ethylene dioxythiophene) with counterion poly(styrene sulphonate), PEDOT:PSS, either in pure form or with additives.

14. A method according to claim 12,
characterized by selecting the PEDOT:PSS cross-linked with a silane-containing compound.

15. A method according to claim 1,
characterized by selecting said printing process as one or more of inkjet printing, screen printing, flexographic printing, offset printing, electrographic printing, soft lithography, laser printing, wax jet printing.

16. A method according to claim 1,
characterized by subjecting at least one layer to a rapid heating process for achieving solvent removal or annealing, using electromagnetic radiation with wavelengths chosen from infrared radiation or microwave radiation.

17. A method according to claim 1,
characterized by performing at least one deposition step in a controlled humidity atmosphere.

18. A method according to claim 1,
characterized by applying a moisture sealing layer in at least one or more of the deposition step.
